(19) United States
(12) Patent Application Publication
(10) Pub. No.: US 2011/0062015 A1
(43) Pub. Date: Mar. 17, 2011

(54) COATING APPARATUS AND COATING METHOD

(75) Inventors: Martin Kutzer, Penig (DE); Andreas Krause, Radebeul (DE); Alexander Fuelle, Kirchberg (DE)

(73) Assignee: SOLARWORLD INNOVATIONS GMBH, Freiberg (DE)

(21) Appl. No.: 12/855,750

(22) Filed: Aug. 13, 2010

(30) Foreign Application Priority Data
Sep. 14, 2009 (DE) 102009041184.4

(51) Int. Cl. C23C 14/35

(52) U.S. Cl. 204/192.12; 204/298.17; 204/298.19

(57) ABSTRACT

An apparatus for coating a substrate with a layer of inhomogeneous but continuous thickness is provided. The apparatus may include a holding device configured to hold a substrate to be coated; a coating device comprising at least one coating source for providing a coating material, which is arranged at a distance from the holding device; and at least one magnetizing device configured to generate a predetermined magnetic field in the region between the substrate to be coated and the coating source. The magnetizing device may be arranged on the opposite side of the holding device to the coating source.

### CROSS-REFERENCE TO RELATED APPLICATION

This application claims priority to German Patent Application Serial No. 10 2009 041 184.4, which was filed Sep. 14, 2009, and is incorporated herein by reference in its entirety.

### TECHNICAL FIELD

Various embodiments relate to an apparatus and a method for coating a substrate. Various embodiments furthermore relate to a semiconductor component including a coated substrate.

### BACKGROUND

During the production of solar cells, a semiconductor substrate is usually provided with a planar rear-side metallization. Said rear-side metallization generally has a constant layer thickness of at least 2 μm. With thinner layer thicknesses, the required transverse conductivity would not be achieved.

### SUMMARY

An apparatus for coating a substrate with a layer of inhomogeneous but continuous thickness is provided. The apparatus may include a holding device configured to hold a substrate to be coated; a coating device comprising at least one coating source for providing a coating material, which is arranged at a distance from the holding device; and at least one magnetizing device configured to generate a predetermined magnetic field in the region between the substrate to be coated and the coating source. The magnetizing device may be arranged on the opposite side of the holding device to the coating source.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic illustration of the method according to an embodiment, and;

FIG. 2 shows a schematic cross section through the apparatus according to an embodiment;

FIG. 3 shows a view of the substrate holder with an arrangement of bar magnets in accordance with an embodiment; and

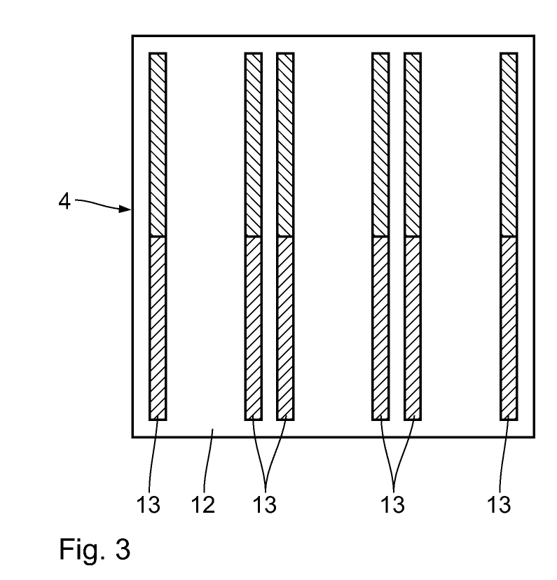

FIGS. 4 to 7 show illustrative examples of semiconductor components with different variants of coatings produced according to an embodiment.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various embodiments may improve an apparatus and a method for coating a substrate. Furthermore, various embodiments provide a semiconductor component having an improved coating.

Various embodiments provide the semiconductor substrate with a coating having an inhomogeneous thickness. In order to achieve this, provision is made for locally influencing the deposition rate on the substrate by means of a magnetic field. For this purpose, the coating apparatus has a magnetizing device, by means of which a predetermined magnetic field can be generated in the region between the substrate to be coated and the coating source. A selective coating of the substrate is thus possible with the apparatus according to various embodiments.

A sputtering device that can be controlled in a simple manner may be provided as the coating device. A sputtering device may enable different substrates to be coated in a simple manner.

Arranging the magnetizing device and the coating source on mutually opposite sides of the holding device ensures that the magnetizing device is not disturbingly in the way during the coating of the substrate.

A magnetizing device having one or a plurality of permanent magnets is structurally particularly simple and robust. On the other hand, electromagnets are flexibly controllable and enable optional temporal and spatial variation of the magnetic field, as a result of which the coating of the substrate is flexibly controllable.

A suitable magnetic field can be achieved, for example, by the arrangement of bar magnets with alternating polarity and at predetermined distances.

The method according to various embodiments may be used to apply a plurality of layers having different thickness distributions to the substrate. In this case, these layers can be composed of different materials.

An exemplary embodiment of the invention is described below with reference to the figures. An apparatus 1 for coating a substrate 2 with a coating 16 includes a holding device 4 for holding the substrate 2 to be coated, a coating device 5 having a coating source 6, and a magnetizing device 7 for generating a magnetic field 15 in the region between the substrate 2 to be coated and the coating source 6.

The substrate 2 is, for example, a semiconductor substrate, for example a silicon wafer, having a first side 8, a second side 9 lying opposite the latter, and a surface normal 10 perpendicular to the sides 8, 9.

The coating 16 includes at least one layer 3.

The holding device 4 serves for mounting the substrate 2, e.g. during coating. It may be embodied in a planar fashion and may have a base 12 with a supporting surface 11 for the substrate 2. It furthermore may have holding elements (not illustrated in the figures) for securely fixing the substrate 2. The holding device 4 may be composed of a diamagnetic or paramagnetic material. The material of the holding device 4 has, for example, a permeability μᵣ of less than 100, e.g. less than 10, e.g. less than 3. By way of example, aluminum, copper or plastic is appropriate as material for the holding device 4.

A sputtering device may be provided as the coating device 5. The coating source 6 is therefore embodied as a sputtering source. The sputtering device includes at least one process chamber for cathode sputtering, to which reduced pressure can be applied. The sputtering source is arranged at a distance from the holding device 4. It can be arranged such that it is fixed or displaceable with respect to the holding device 4. It is advantageous, for example, to arrange the sputtering source such that it is displaceable in a direction parallel to the supporting surface 11 of the holding device 4. In principle, the coating device 5 can also have a plurality of sputtering sources. It is advantageous, for example, if the coating device 5 has at least two, e.g. a plurality of sputtering sources. The sputtering sources can be arranged in a predefined grid of rows and columns. In this case, the arrangement or the form or the arrangement and the form of the sputtering sources may correspond to the subsequent soldering positions. For applying layers 3 composed of different materials, the sputtering sources can have targets composed of different materials. In various embodiments, aluminum, silver, nickel and tin are appropriate as materials for the coating 16. The form and arrangement of the targets is in various embodiments adapted to the form of the substrate 2 to be coated or to the desired form of the coating 16. Sputtering sources 6 having a grid of rectangular or round targets are possible, for example. A combination of rectangular and round targets is likewise possible.

The magnetizing device 7 serves for generating a predetermined, in various embodiments an inhomogeneous, magnetic field in the region between the substrate 2 to be coated and the coating source 6. The magnetic field that can be generated by means of the magnetizing device 7 may have a periodicity in a direction perpendicular to the surface normal 10, that is to say in a direction parallel to the supporting surface 11.

The magnetizing device 7 is in various embodiments arranged on the opposite side of the holding device 4 to the coating source 6. However, it is also possible to arrange the magnetizing device 7 in such a way that the coating source 6 is arranged between the magnetizing device 7 and the holding device 4. Moreover, it is possible for the magnetizing device 7 to be embodied in such a way that it surrounds the region between the coating source 6 and the holding device 4. In various embodiments, a ring-shaped embodiment of the magnetizing device 7 is conceivable. It is crucial that no disturbing parts be situated between the coating source 6 and the holding device 4, that is to say that the region between the coating source 6 and the holding device 4 be free of obstacles.

In various embodiments, the magnetizing device 7 is integrated into the holding device 4. It can be arranged, for example, on that side of the base 12 of the holding device 4 which lies opposite the supporting surface 11.

As an alternative to this it is also conceivable to integrate the magnetizing device 7 into the coating device 5.

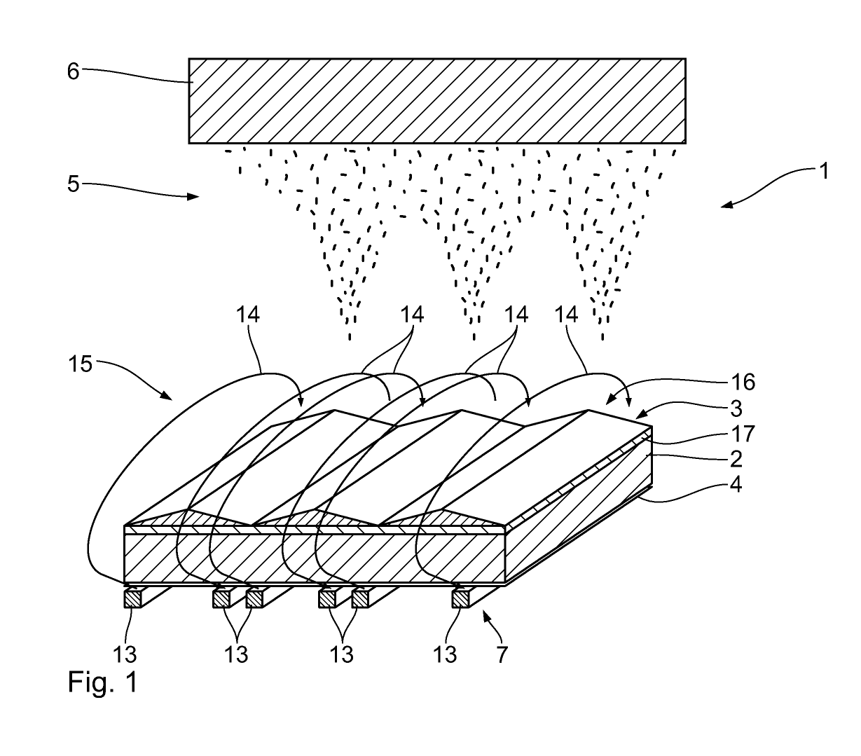

The magnetizing device 7 includes at least one, in various embodiments a plurality of magnets 13. In accordance with various embodiments illustrated in the figures, the magnets 13 may be embodied as permanent magnets. However, it is likewise possible for one or a plurality of the magnets 13 to be embodied as electromagnets. A combination of permanent magnets and electromagnets is also possible. The magnets 13 are embodied as bar magnets, for example. They are arranged parallel to the supporting surface 11. They can be fixed to the base 12. The magnets 13 are arranged parallel to one another. They are arranged at predetermined distances from one another. In order to generate a suitable magnetic field 15, provision is made, for example, for arranging the magnets 13 alternately at a first distance D1 and a second distance D2 from one another, wherein the first distance D1 is at least twice, in particular at least four times, as large as the second distance D2. In the case of this arrangement, provision is made for orienting the magnets 13 with alternating polarity. Field lines 14 of the corresponding magnetic field 15 are illustrated schematically in FIG. 1.

The magnetic field 15 that can be generated by means of the magnetizing device 7 has regions having field strengths of different magnitudes in a direction parallel to the supporting surface 11. In this case, regions having a higher field strength and regions having a lower field strength alternate in a predetermined, regular, in various embodiments, periodically repeating pattern.

The method according to various embodiments for coating the substrate 2 with a coating 16 is described below. The substrate 2 is placed by its first side 8 onto the supporting surface 11 of the holding device 4 and suitably fixed there.

On the second side 9 lying opposite the first side 8, the substrate 2 is provided with a dielectric passivation layer 17. The dielectric passivation layer 17 is composed of silicon dioxide or silicon nitride, for example.

The holding device 4 with the substrate 2 is then arranged with respect to the coating device 5 in such a way that the coating source 6 is arranged opposite the second side 9, to be coated, of the substrate 2. By means of the coating device 5, the layer 3 of the coating 16 is then applied to the passivation layer 17 on the second side 9 of the substrate 2. The layer 3 is embodied in a planar fashion. It covers the passivation layer 17 in various embodiments over the whole area, that is to say completely. Only partial coverage of the passivation layer 17 is likewise possible. It can have, for example, deposition islands, that is to say unconnected regions. The coating 16 may include one or a plurality of layers 3. The layers 3 can be composed of different materials. As an alternative or in addition to this, they can have a different thickness distribution.

The coating 16 has, in various embodiments, a layer 3 composed of aluminum. Further layers 3 composed, in various embodiments, of silver, nickel or tin are possible.

Upon emerging from the sputtering source, the material for coating the substrate 2 is ionized. During the coating of the substrate 2, the coating material has an ionization proportion of at least 25%, e.g. at least 50%, e.g. at least 90%. On account of its electrical charge, the coating material released by the sputtering source experiences a Lorentz force on its way from the sputtering source to the substrate 2 in the magnetic field 15. The Lorentz force is proportional to the field strength of the magnetic field 15. On account of the Lorentz force, the individual constituents of the coating material are deflected to a greater or lesser extent on their way from the sputtering source to the substrate 2. The deposition rate is thereby increased locally in predetermined regions on the substrate 2. A thickening 18 of the coating 16 can be observed in these regions. The thickenings 18 can have different cross sections. In various embodiments, rounded, roof-gable-like or polygonal cross sections are conceivable. In other regions, the deposition rate is decreased locally.

By means of a suitable embodiment of the magnetic field 15, that is to say by means of a suitable distribution of the field strength of the magnetic field 15 in the region between the sputtering source and the substrate 2, it is possible to flexibly influence the deposition rate in predetermined, local regions on the substrate 2. In the case of a magnetizing device 7 having electromagnets, the magnetic field 15 can be varied spatially and also, in various embodiments, temporally by suitable control of at least one of the electromagnets.

On account of the spatial variation of the deposition rate on the substrate 2, the layer 3 and thus the coating 16 has an inhomogeneous thickness in a direction perpendicular to the surface normal 10. However, the thickness of the coating 16 on the substrate 2 has a continuous profile. Provision is made for locally increasing the deposition rate at the positions at which contact structures or cell connectors are intended subsequently to be soldered. In other words, the thickness of the coating 16 thus increases with increasing proximity to the soldering positions. This takes account of the fact that the current to be transported through the coating 16 increases toward the soldering positions. However, since the ohmic resistance is reduced as the thickness of the coating 16 increases, the power loss that arises as a result of the ohmic resistance of the coating 16 remains constant or is even reduced.

In order to produce an electrical contact between the coating 16, in various embodiments between the layer 3 composed of aluminum, and the substrate 2, a laser method is provided. With regard to details of the production of the electrical contact between the coating 16 and the substrate 2, reference should be made to DE 10 2009 010 816 A1.

According to various embodiments, further layers 3, in various embodiments a diffusion barrier layer and a soldering layer may be applied according to the same method. In various embodiments, provision may be made for improving the solderability of the coating 16 by applying at least one further layer 3. Suitable materials for this purpose are, for example, nickel or a layer stack composed of titanium and silver, wherein the titanium functions as a diffusion barrier and prevents the diffusion of aluminum from the first layer 3 into the solderable silver layer.

In order to reduce the mechanical stresses in the substrate 2 after coating, provision may be made for the substrate 2 to be at least partly provided with a masking during coating. In various embodiments, the magnetizing device 7 is precisely embodied such that the locations with a reduced deposition rate precisely correspond to the positioning of the masking, such that the amount of material that remains on the masking is reduced.

A further advantage of the method according to various embodiments is that the required layer thickness can be achieved in a shorter time on account of the locally increased deposition rate.

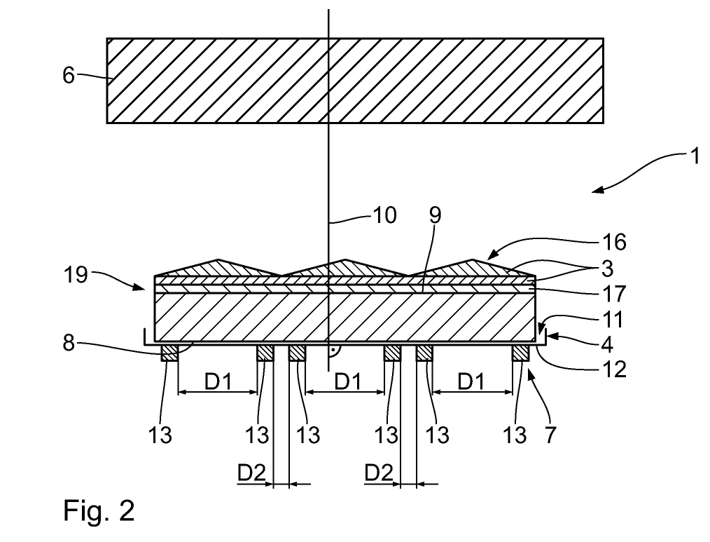

As illustrated in FIG. 2, the first layer 3 of the coating 16 can also be applied with a constant layer thickness. Afterward, at least one further layer 3 is applied with a locally increased deposition rate, that is to say with an inhomogeneous thickness. In this case, an at least partial masking of the substrate 2 can again be provided. By means of a masking, the thickness of the coating 16 can be varied even more flexibly and more precisely. Given a suitable orientation of the magnetic field 15, the masking is subjected only to a low deposition rate, such that the amount of material remaining on the masking is reduced.

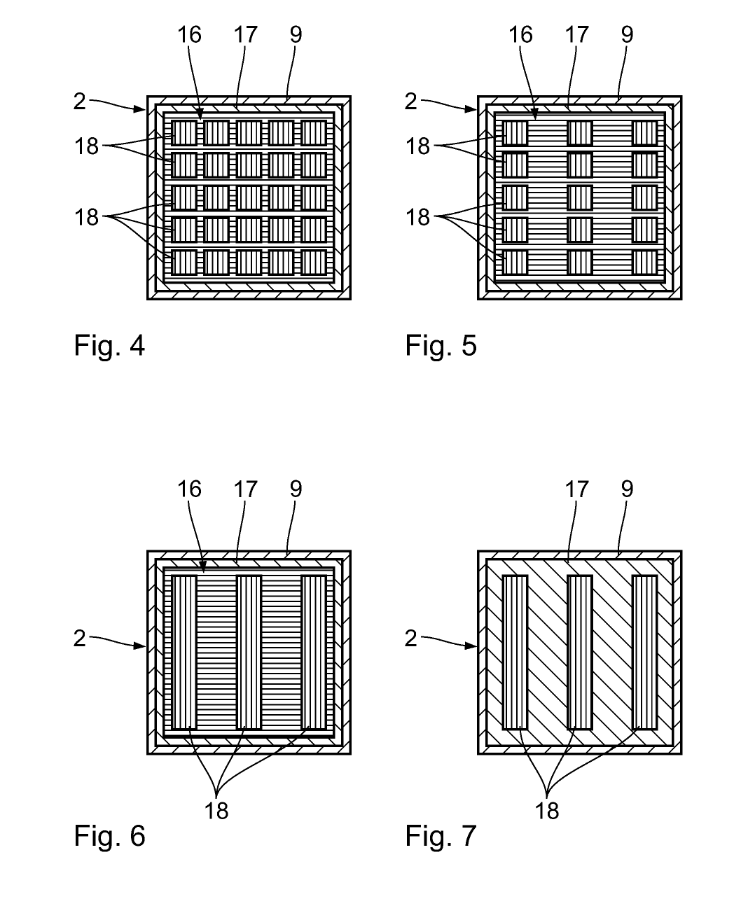

It may be advantageous for the substrate 2 to be at least partly provided with a masking during the application of at least one of the layers 3. It goes without saying that different maskings can be used during the application of different layers 3. Illustrative examples of the correspondingly applied coatings 16 are illustrated in FIGS. 4 to 7. In this case, the thickenings 18 of the coating 16 are identified schematically. As illustrated in FIGS. 4 to 7, the coating 16 can have, in various embodiments, a series of strip-type thickenings 18 arranged parallel to one another, or a grid composed of a predetermined number of rows and columns of rectangular, in various embodiments square, thickenings 18. As illustrated in FIG. 7, the thickness of the coating 16 can also be reduced to zero in the regions between the thickenings 18.

A semiconductor component 19 coated according to various embodiments is described hereinafter. The semiconductor component 19 is a solar cell, in various embodiments. The semiconductor component 19 includes the semiconductor substrate 2. The semiconductor substrate 2 is provided with a passivation layer 17 at least on the second side 9. A coating 16 is applied to said passivation layer. The coating 16 includes one or a plurality of layers 3. According to various embodiments, the coating 16 has an inhomogeneous thickness in a direction perpendicular to the surface normal 10. The thickness of the coating 16 has a continuous profile, in various embodiments. The embodiment of the coating 16 is evident from the description above.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An apparatus for coating a substrate with a layer of inhomogeneous but continuous thickness, the apparatus comprising:
a holding device configured to hold a substrate to be coated;
a coating device comprising at least one coating source for providing a coating material, which is arranged at a distance from the holding device; and
at least one magnetizing device configured to generate a predetermined magnetic field in the region between the substrate to be coated and the coating source;
wherein the magnetizing device is arranged on the opposite side of the holding device to the coating source.

2. The apparatus as claimed in claim 1,
wherein a sputtering device comprising at least one process chamber for cathode sputtering, to which reduced pressure can be applied, is provided as the coating device.

3. The apparatus as claimed in claim 1,
wherein the magnetizing device is arranged or embodied in such a way that the region between the coating source and the holding device is free of obstacles.

4. The apparatus as claimed in claim 1,
wherein the magnetizing device comprises at least one magnet.

5. The apparatus as claimed in claim 4,
wherein the magnetizing device comprises a plurality of magnets.

6. The apparatus as claimed in claim 4,
wherein the at least one magnet is embodied as a permanent magnet or as a electromagnet.

7. The apparatus as claimed in claim 4,
wherein the at least one magnet is configured such that a magnetic field generated by means of the at least one magnet is temporally or spatially variable.

8. The apparatus as claimed in claim 4,
wherein the at least one magnet is embodied as a bar magnet.

9. The apparatus as claimed in claim 5,
wherein the magnets are arranged at predetermined distances from one another.

10. The apparatus as claimed in claim 5,
wherein the magnets are arranged alternately at a first distance and a second distance from one another, wherein the first distance is at least twice as large as the second distance.

11. The apparatus as claimed in claim 10,
wherein the magnets are arranged alternately at a first distance and a second distance from one another, wherein the first distance is at least four times as large as the second distance.

12. The apparatus as claimed in claim 5,
wherein the magnets are oriented with alternating polarity.

13. A method for coating a substrate, the method comprising:
providing a substrate comprising a first side, a second side to be coated, which lies opposite said first side, and a surface normal perpendicular to the sides;
providing an apparatus for coating a substrate with a layer of inhomogeneous but continuous thickness, the apparatus comprising:
a holding device configured to hold a substrate to be coated;
a coating device comprising at least one coating source for providing a coating material, which is arranged at a distance from the holding device; and
at least one magnetizing device configured to generate a predetermined magnetic field in the region between the substrate to be coated and the coating source;
wherein the magnetizing device is arranged on the opposite side of the holding device to the coating source.
applying a coating to the second side of the substrate at least in regions by means of the coating device;
wherein the coating has an inhomogeneous thickness in a direction perpendicular to the surface normal.

14. The method as claimed in claim 13,
wherein the deposition rate on the substrate is increased locally in at least one predetermined region on the substrate by means of the magnetic field generated by means of the magnetizing device.

15. The method as claimed in claim 13,
wherein the magnetic field that can be generated by means of the magnetizing device is temporally or spatially controllable during coating.

16. The method as claimed in claim 13,
wherein the coating comprises a plurality of layers.

17. The method as claimed in claim 16,
wherein the plurality of layers are composed of different materials or have a different thickness distribution.
